(19) United States
(12) Patent Application Publication
(10) Pub. No.: US 2018/0224498 A1
(43) Pub. Date: Aug. 9, 2018

(54) METHOD OF TESTING SEMICONDUCTOR DEVICE AND TEST SYSTEM PERFORMING THE METHOD

(71) Applicant: Samsung Electronics Co., Ltd., Suwon-si (KR)

(72) Inventors: Jae Su Jung, Suwon-si (KR); Jae Won Lee, Suwon-si (KR)

(21) Appl. No.: 15/867,890

(22) Filed: Jan. 11, 2018

(30) Foreign Application Priority Data
Feb. 3, 2017 (KR) 10-2017-0015413

(51) Int. Cl. G01R 31/28

(52) U.S. Cl. CPC G01R 31/2848; G01R 31/2837; G01R 31/2894

(57) ABSTRACT

A method of testing a semiconductor device includes: measuring minimum operating voltages of a plurality of semiconductor devices and operating frequencies of first and second ring oscillators included in the semiconductor devices, wherein the first ring oscillators have a first circuit configuration and the second ring oscillators have a second circuit configuration different from the first circuit configuration; generating a first model representing a correlation between operating frequencies of the first ring oscillators in the semiconductor devices and the minimum operating voltages of the semiconductor devices; generating a second model representing a correlation between operating frequencies of the second ring oscillators in the semiconductor devices and the minimum operating voltages of the semiconductor devices; measuring the operating frequencies of the first ring oscillators and the second ring oscillators included in a target semiconductor device; calculating a first measurement value using the operating frequencies of the first ring oscillators in the target semiconductor device and the first model; calculating a second measurement value using the operating frequencies of the second ring oscillators in the target semiconductor device and the second model; determining a high temperature compensation voltage of the target semiconductor device based on the first measurement value and the second measurement value; and modifying a dynamic voltage and frequency scaling (DVFS) table of the target semiconductor device according to the high temperature compensation voltage.

### CROSS-REFERENCE TO RELATED APPLICATION

This application claims priority under 35 U.S.C. 119 from Korean Patent Application No. 10-2017-0015413 filed on Feb. 3, 2017, the disclosure of which is hereby incorporated by reference in its entirety.

### BACKGROUND

### 1. Field

The present inventive concepts relate to a method of testing a semiconductor device and a test system performing the method. More particularly, the present inventive concepts relate to a method and system for testing a semiconductor device by generating a model representing a correlation between a minimum operating voltage of a semiconductor device and operating frequencies of ring oscillators included in the semiconductor device and using the generated model.

### 2. Description of the Related Art

Various tests are performed on a manufactured semiconductor device to secure operational reliability, and a plurality of operating parameters are set based on the test results. A type and number of such tests tend to increase gradually in order to prepare for various environmental variables expected in the operation of semiconductor devices.

The plurality of operating parameters may have a certain correlation with each other. Thus, if one operating parameter is measured, the tendency of other parameters may be predicted based on the correlation, and, as a result, the test speed and throughput of semiconductor devices may be improved.

### SUMMARY

Aspects of the inventive concepts provide a method of testing a semiconductor device, in which a difference between minimum operating voltages of a semiconductor device in a room temperature environment and in a high temperature environment is predicted using a correlation between ring oscillators having different circuit configurations in the semiconductor device and a minimum operating voltage of the semiconductor device.

Aspects of the inventive concepts also provide a system for testing a semiconductor device, the system capable of predicting a difference between minimum operating voltages of a semiconductor device or chip in a room temperature environment and in a high temperature environment using a correlation between ring oscillators having different circuit configurations in the semiconductor device and a minimum operating voltage of the semiconductor device.

In one aspect, the present inventive concepts are directed to a method of testing a semiconductor device includes measuring minimum operating voltages of a plurality of semiconductor devices and operating frequencies of first and second ring oscillators included in the semiconductor devices. The first ring oscillators include a first circuit configuration and the second ring oscillators include a second circuit configuration different from the first circuit configuration. The method further includes generating a first model representing a correlation between the operating frequencies of the first ring oscillators in the semiconductor devices and the minimum operating voltages of the semiconductor devices, generating a second model representing a correlation between the operating frequencies of the second ring oscillators in the semiconductor devices and the minimum operating voltages of the semiconductor devices, measuring operating frequencies of first ring oscillators and second ring oscillators included in a target semiconductor device, calculating a first measurement value using the operating frequencies of the first ring oscillators in the target semiconductor device and the first model, calculating a second measurement value using the operating frequencies of the second ring oscillators in the target semiconductor device and the second model, determining a high temperature compensation voltage of the target semiconductor device based on the first measurement value and the second measurement value and modifying a dynamic voltage and frequency scaling (DVFS) table of the target semiconductor device according to the high temperature compensation voltage.

In another aspect, the present inventive concepts are directed to a system for testing a semiconductor device includes a measuring unit which measures minimum operating voltages of a plurality of semiconductor devices and operating frequencies of first and second ring oscillators included in the semiconductor devices. The first ring oscillators include a first circuit configuration and the second ring oscillators include a second circuit configuration different from the first circuit configuration. The system further includes a model generation unit which generates a first model between the operating frequencies of the first ring oscillators in the semiconductor devices and the minimum operating voltages of the semiconductor devices and generates a second model between the operating frequencies of the second ring oscillators in the semiconductor devices and the minimum operating voltages of the semiconductor devices, and a calculation unit which receives operating frequencies of first ring oscillators and second ring oscillators included in a target semiconductor device from the measuring unit, calculates a first measurement value using the operating frequencies of the first ring oscillators in the target semiconductor device and the first model, calculates a second measurement value using the operating frequencies of the second ring oscillators in the target semiconductor device and the second model, and determines a high temperature compensation voltage of the target semiconductor device based on the first measurement value and the second measurement value.

In another aspect, the present inventive concepts are directed to a method of testing a semiconductor device. The method includes measuring a minimum operating voltage of at least one functional block included in each of a plurality of semiconductor devices and operating frequencies of first and second ring oscillators included in the at least one functional block. The first ring oscillators comprise a first circuit configuration and the second ring oscillators comprise a second circuit configuration different from the first circuit configuration. The method further includes generating a first model representing a correlation between the operating frequencies of the first ring oscillators in the at least one functional block and the minimum operating voltage of the at least one functional block, generating a second model representing a correlation between the operating frequencies of the second ring oscillators in the at least one functional block and the minimum operating voltage of the at least one functional block, measuring operating frequencies of first ring oscillators and second ring oscillators included in a target semiconductor device, calculating a first measurement value using the operating frequencies of the first ring oscillators in the target semiconductor device and the first model, calculating a second measurement value using the operating frequencies of the second ring oscillators in the target semiconductor device and the second model; and determining a high temperature compensation voltage of the target semiconductor device based on the first measurement value and the second measurement value.

### BRIEF DESCRIPTION OF THE DRAWINGS

These and/or other aspects and advantages of the present general inventive concepts will become apparent and more readily appreciated from the following description of the embodiments, taken in conjunction with the accompanying drawings in which:

FIG. 1 is a block diagram of a semiconductor device to which a method of testing a semiconductor device according to some embodiments of the present inventive concepts may be applied;

FIG. 2 is a partial block diagram of a functional block of the semiconductor device of FIG. 1 according to some embodiments of the present inventive concepts;

FIGS. 3A and 3B are circuit diagrams of ring oscillators of the functional block of FIG. 2 according to some embodiments of the present inventive concepts;

FIGS. 4A and 4B are partial circuit diagrams of ring oscillators of the functional block of FIG. 2 according to some embodiments of the present inventive concepts;

FIG. 5 is a flowchart illustrating a method of testing a semiconductor device according to some embodiments of the present inventive concepts;

FIG. 6 is a schematic diagram illustrating a process included in the method of testing a semiconductor device according to the embodiment of FIG. 5;

FIG. 7 is a schematic diagram illustrating a table obtained by performing the method of testing a semiconductor device according to the embodiment of FIG. 5;

FIG. 8 is a flowchart illustrating a method of testing a semiconductor device according to some embodiments of the present inventive concepts;

FIG. 9 is a flowchart illustrating a method of testing a semiconductor device according to some embodiments of the present inventive concepts;

FIG. 10 is a block diagram of a semiconductor device to which the method of testing a semiconductor device according to the embodiment of FIG. 9 may be applied; and

FIG. 11 is a block diagram of a system for testing a semiconductor device according to some embodiments of the present inventive concepts.

### DETAILED DESCRIPTION

Reference will now be made in detail to the embodiments of the present general inventive concepts, examples of which are illustrated in the accompanying drawings, wherein like reference numerals refer to the like elements throughout. The embodiments are described below in order to explain the present general inventive concepts by referring to the figures.

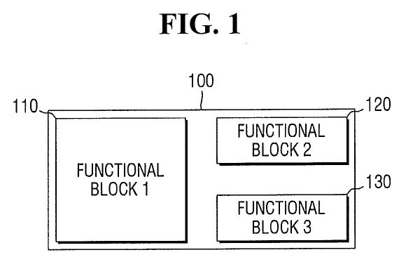

Methods of testing a semiconductor device according to some embodiments will hereinafter be described with reference to FIGS. 1 through 11.

FIG. 1 is a block diagram of a semiconductor device or chip 100 to which a method of testing a semiconductor device according to some embodiments of the present inventive concepts may be applied.

Referring to FIG. 1, the method of testing a semiconductor device according to some embodiments of the present inventive concepts may be performed on the semiconductor device 100.

The semiconductor device 100 may be, for example, a memory chip or a logic chip. In an embodiment in which the semiconductor device 100 is a memory chip or a logic chip, the memory chip or logic chip may be designed in various ways in consideration of operations to be performed by the semiconductor device 100.

In an embodiment in which the semiconductor device 100 is a memory chip, the memory chip may be, for example, a nonvolatile memory chip. Specifically, the memory chip may be a flash memory chip. More specifically, the memory chip may be any one of a NAND flash memory chip and a NOR flash memory chip.

However, the form of the memory chip to which the test method according to the embodiment of the present inventive concepts may be applied is not limited to the above examples. In some embodiments, the memory chip may be, for example, a volatile memory chip. Specifically, the memory chip may be, but is not limited to, a random access memory (DRAM), a static random access memory (SRAM), or an embedded RAM.

In an embodiment in which the semiconductor device 100 is a logic chip, the logic chip may include, but is not limited to, a central processing unit (CPU), a graphics processing unit (GPU), an application processor (AP), and a field programmable grid array (FPGA).

The method of testing a semiconductor device according to the embodiment of the present inventive concepts will be described on the assumption that the semiconductor device 100 is an AP.

The semiconductor device 100 may include a plurality of functional blocks 110, 120 and 130. In FIG. 1, the semiconductor device 100 includes three functional blocks 110 through 130; however, the number of functional blocks included in the semiconductor device 100 is not limited thereto. In other embodiments, the semiconductor device 100 may include more than or less than three functional blocks according to design intent.

In an embodiment in which the semiconductor device 100 is an AP as described above, the first functional block 110 may be a big core, the second functional block 120 may be a little core, and the third functional block 130 may be a GPU.

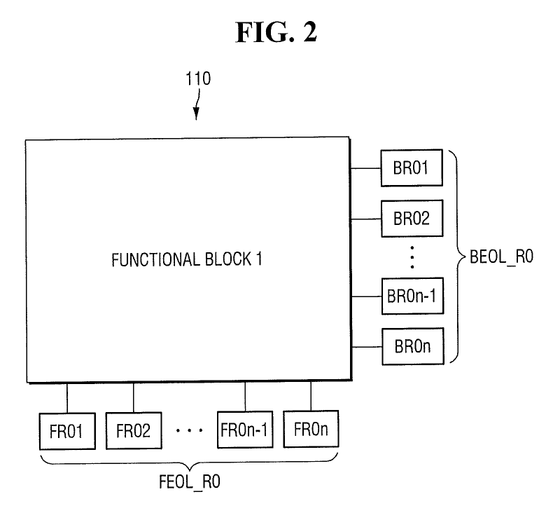

FIG. 2 is a partial block diagram of the functional block 110 of the semiconductor device 100 of FIG. 1 according to some embodiments of the present inventive concepts.

Referring to FIG. 2, the first functional block 110 is illustrated in greater detail. The first functional block 110 may include a plurality of ring oscillators RO in addition to circuit components constituting the first functional block 110. In some embodiments, the semiconductor device 100 may include first ring oscillators FEOL_RO and second ring oscillators BEOL_RO having different configurations. More specifically, the first ring oscillators FEOL_RO may be front end of line (FEOL) ring oscillators, and the second ring oscillators BEOL_RO may be back end of line (BEOL) ring oscillators. The first ring oscillator FEOL_RO may include a plurality of first ring oscillators FRO1 through FROn. The second ring oscillator BEOL_RO may include a plurality of second ring oscillators BRO1 through BROn.

In addition, the first functional block 110 may store a dynamic voltage and frequency scaling (DVFS) table for performing DVFS between an operating frequency at which the first functional block 110 operates and an operating voltage. Before a method of testing a semiconductor device according to some embodiments of the present inventive concepts is performed, a minimum operating voltage according to the operating frequency may be stored in advance in the DVFS table. As the method of testing a semiconductor device according to the embodiments of the present inventive concepts is performed, the DVFS table may be modified to ensure the normal operation of the semiconductor device 100 in a high temperature condition.

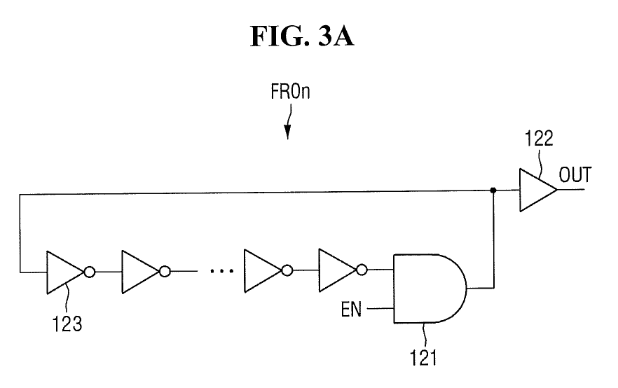

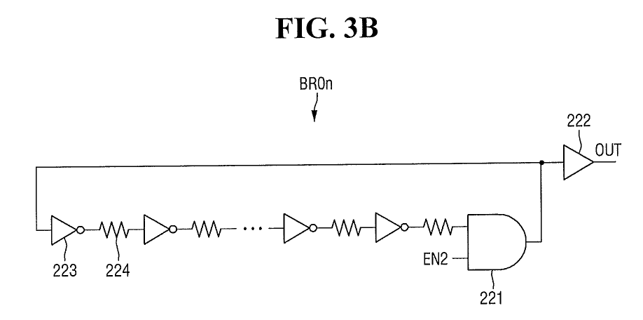

The first and second ring oscillators FEOL_RO and BEOL_RO having different configurations in the semiconductor device 100 will be described in more detail with reference to FIGS. 3A and 3B.

FIGS. 3A and 3B are circuit diagrams of the ring oscillators FROn and BROn, respectively, of the functional block 110 of FIG. 2 according to some embodiments of the present inventive concepts.

Referring to FIG. 3A, one of the plurality of first ring oscillators FROn may include a plurality of NOT gates (or inverters) 123 connected in series and an AND gate 121 and a buffer 122 connected to an output of the first ring oscillator FROn. The AND gate 121 may be coupled between the final NOT gate 123 of the plurality of NOT gates 123 and the buffer 122.

The first ring oscillator FROn may include an odd number of NOT gates 123. The odd number of NOT gates 123 are connected in a ring structure in which an output of one NOT gate 123 is provided to an input of another NOT gate 123. An output voltage OUT of the first ring oscillator FROn may be output via the buffer 122 and may oscillate between two voltage levels TRUE and FALSE. The AND gate 121 provides an output to the buffer 122 and a first NOT gate 123 of the plurality of NOT gates 123 in response to an enable signal EN. That is, a first input of the AND gate 121 receives an output from the final NOT gate 123 of the plurality of NOT gates and a second input of the AND gate 121 receives the enable signal EN.

Referring to FIG. 3B, one of the plurality of second ring oscillators BROn may include a plurality of NOT gates 223 connected in series and an AND gate 221 and a buffer 222 connected to an output of the second ring oscillator BEOL_RO.

The second ring oscillator BEOL_RO may have a structure similar to the structure of the first ring oscillator FEOL_RO described above. That is, the second ring oscillator BEOL_RO has a ring structure including an odd number of NOT gates 223, and an output voltage OUT of the second ring oscillator BEOL_RO is output via the buffer 222 to oscillate between two voltage levels TRUE and FALSE. The AND gate 221 provides an output to the buffer 222 and a first NOT gate 223 of the plurality of NOT gates in response to an enable signal EN2.

In the second ring oscillator BEOL_RO, however, a resistor 224 may be connected between two NOT gates 223. That is, an output of one NOT gate 223 is provided to an input of another NOT gate 223 via the resistor 224. The AND gate 221 may be coupled between the final resistor 224 connected to the final NOT gate 223 of the plurality of NOT gates 223 and the buffer 222. A first input of the AND gate 221 receives an output from the final resistor 224 connected to the final NOT gate 223 and a second input of the AND gate 221 receives the enable signal EN2.

In general, a semiconductor device 100 to which a method of testing a semiconductor device according to some embodiments of the present inventive concepts is applied may include a large number of transistors. Operating characteristics of transistors may include threshold voltages VT of the transistors and response speeds of the transistors.

Of the operating characteristics, response speed characteristics of the transistors included in the semiconductor device 100 may be indicated by the first and second ring oscillators FEOL_RO and BEOL_RO. That is, how many times the outputs OUT of the first and second ring oscillators FEOL_RO and BEOL_RO oscillated for a predetermined period of time in response to a provided input may indicate the response speed characteristics of the transistors included in the semiconductor device 100.

The second ring oscillator BEOL_RO may indicate thermal characteristics of the semiconductor device 100 in addition to the response speed characteristics of the semiconductor device 100.

In general, operating characteristics of semiconductor elements constituting the semiconductor device 100 can be changed by the influence of external environmental factors. In particular, as the semiconductor device 100 operates at a high speed, the response speed of the semiconductor device may be changed by resistance components in the circuit of the semiconductor device 100, and the change in the response speed may indicate the thermal characteristics of the circuit of the semiconductor device 100.

In the second ring oscillator BEOL_RO, two NOT gates 223 of the plurality of NOT gates 123 are connected to each other with the resistor 224 interposed between them. That is, the resistors 224 are connected between adjacent NOT gates 223 of the plurality of NOT gates 223 and between the final NOT gate 223 of the plurality of NOT gates 223 and the AND gate 221. As a result of the resistors 224 included in the second ring oscillator BEOL_RO, the speed characteristics of the second ring oscillator BEOL_RO may indicate the thermal characteristics of the semiconductor device 100. In a method of testing a semiconductor device according to the embodiments of the present inventive concepts, the thermal characteristics of the semiconductor device 100 may indicate a change in the operating speed of the semiconductor device 100 in a high temperature environment.

Therefore, the operating characteristics of the semiconductor device 100 in the high temperature environment may be modeled using the speed characteristics of the second ring oscillator BEOL_RO, and operating characteristics of a target semiconductor device in the high temperature environment may be predicted based on the modeled operating characteristics.

In addition, the operating characteristics of the first and second ring oscillators FEOL_RO and BEOL_RO in the semiconductor device 100 may have a certain relationship with a minimum operating voltage, for example, a low VCC (LVCC), of the semiconductor device 100. In the method of testing a semiconductor device according to the embodiments of the present inventive concepts, characteristics of a semiconductor to be measured may be predicted using the relationship between the operating characteristics of the ring oscillators FEOL_RO and BEOL_RO and the minimum operating voltage of the semiconductor device 100, as will be described in more detail later.

In some embodiments, an operating frequency of the first ring oscillator FEOL_RO and an operating frequency of the second ring oscillator BEOL_RO may be different. Specifically, the operating frequency of the first ring oscillator FEOL_RO may be greater than the operating frequency of the second ring oscillator BEOL_RO. The difference in operating frequencies may be a result of the resistance components included in the second ring oscillator BEOL_RO.

Referring to FIG. 2, the first functional block 110 includes a plurality of first ring oscillators FEOL_RO and a plurality of second ring oscillators BEOL_RO. However, it will be apparent to those of ordinary skill in the art to which the present inventive concepts pertains that the second functional block 120 and the third functional block 130 may each include a plurality of ring oscillators.

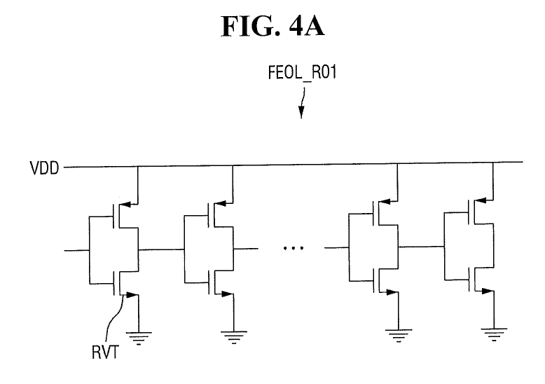

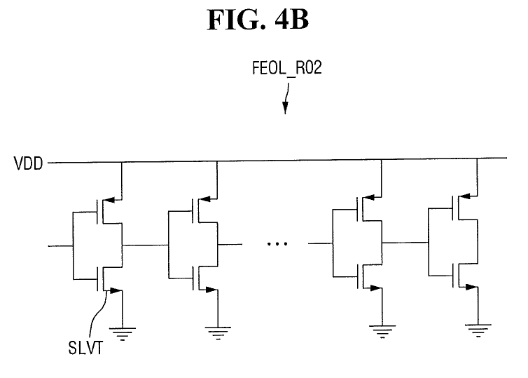

FIGS. 4A and 4B are partial circuit diagrams of ring oscillators of a functional block according to some embodiments of the present inventive concepts.

Referring to FIGS. 4A and 4B, circuit diagrams of ring oscillators to which a method of testing a semiconductor device according to the embodiments of the present inventive concepts is applied are illustrated. FIGS. 4A and 4B illustrate various embodiments of the first ring oscillators FEOL_RO of FIG. 2. In FIGS. 4A and 4B, first ring oscillators FEOL_RO1 and FEOL_RO2, respectively, consist of a plurality of transistors connected to each other between a voltage VDD and ground.

For example, the first ring oscillator FEOL_RO1 illustrated in FIG. 4A may be composed of transistors RVT having a regular voltage threshold. The first ring oscillator FEOL_RO1 composed of the transistors RVT may exhibit characteristics of a general ring oscillator.

The first ring oscillator FEOL_RO2 illustrated in FIG. 4B may be composed of transistors SLVT having a super low threshold voltage. The first ring oscillator FEOL_RO2 composed of the transistors SLVT may have a very high operating speed. The above types of transistors are merely examples, and the present inventive concepts are not limited to these examples.

Although not illustrated, transistors constituting the second ring oscillator BEOL_RO may also be composed of various types of transistors such as the regular voltage threshold transistors RVT and the super low threshold voltage transistors SLVT.

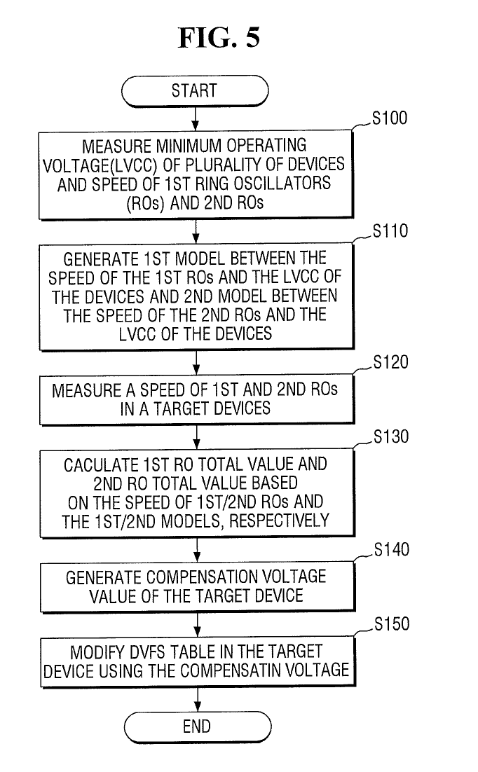

FIG. 5 is a flowchart illustrating a method of testing a semiconductor device according to some embodiments of the present inventive concepts. For example, FIG. 5 illustrates a method of testing the semiconductor device 100 of FIG. 1.

Referring to FIG. 5, the method of testing a semiconductor device may include measuring minimum operating voltages (LVCC) of a plurality of semiconductor devices, or semiconductor chips, and operating frequencies, that is, speeds, of first and second ring oscillators FEOL_RO and BEOL_RO included in the plurality of the semiconductor devices (operation S100). The method further includes generating a first model between the minimum operating voltages of the plurality of semiconductor devices and the operating frequencies of the first ring oscillators FEOL_RO included in the plurality of the semiconductor devices and generating a second model between the minimum operating voltages of the plurality of the semiconductor devices and the operating frequencies of the second ring oscillators BEOL_RO included in the plurality of semiconductor devices (operation S110). The method further includes measuring operating frequencies of the first ring oscillators FEOL_RO and the second ring oscillators BEOL_RO in a target semiconductor device (operation S120). The method further includes calculating a first measurement value FEOL_RO TOTAL VALUE using the operating frequencies of the first ring oscillators FEOL_RO of the target semiconductor device and the first model and calculating a second measurement value BEOL_RO TOTAL VALUE using the operating frequencies of the second ring oscillators BEOL_RO of the target semiconductor device and the second model (operation S130). The method further includes determining a high temperature compensation voltage of the target semiconductor device based on the first measurement value FEOL_RO TOTAL VALUE and the second measurement value BEOL_RO TOTAL VALUE (operation S140), and modifying a DVFS table using the high temperature compensation voltage (operation S150).

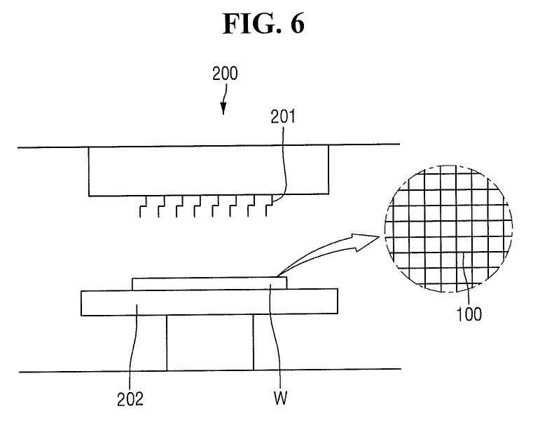

Specifically, minimum operating voltages (LVCC) of the plurality of semiconductor devices and operating frequencies of the first ring oscillators FEOL_RO and the second ring oscillators BEOL_RO included in the semiconductor devices are measured (S100). This will be described in more detail with reference to FIG. 6.

FIG. 6 is a schematic diagram illustrating a process included in the method of testing a semiconductor device according to the embodiment of FIG. 5.

Referring to FIG. 6, minimum operating voltages (LVCC) of a plurality of semiconductor devices 100, as illustrated in FIGS. 1 through 3B, included in a wafer W and operating frequencies of the first and second ring oscillators FEOL_RO and BEOL_RO included in the semiconductor devices 100 are measured by measurement equipment 200.

The minimum operating voltages of the semiconductor devices 100 and the operating frequencies of the first and second ring oscillators FEOL_RO and BEOL_RO may be measured by mounting the wafer W on a stage 202, transmitting test signals to the wafer W using probes 201, and receiving output signals from the wafer W using probes 201.

In some embodiments, the measuring process may be performed during the process of manufacturing the semiconductor devices 100. That is, the measuring process may be performed in an electrical die sorting (EDS) process after the semiconductor devices 100 are formed on the wafer W and before the semiconductor devices 100 are sawed and packaged.

As described above, each of the semiconductor devices 100 on the wafer W may include a plurality of first ring oscillators FEOL_RO and a plurality of second ring oscillators BEOL_RO, and each of the first and second ring oscillators FEOL_RO and BEOL_RO may include an input pad and an output pad. These pads may not be exposed after the semiconductor devices 100 are packaged and may be accessible externally only before the semiconductor devices 100 are packaged. Therefore, the operating frequency of each ring oscillator may be measured during the EDS process.

The minimum operating voltage of the semiconductor device 100 refers to the lowest level of a power supply voltage that should be supplied to the semiconductor device in order for normal operation of the semiconductor device 100. The semiconductor device 100 may be tested at a plurality of minimum operating voltage levels to determine if the semiconductor device 100 operates normally, and the minimum operating voltage may be set based on a lowest power supply voltage at which the semiconductor device 100 operates normally.

As described above, operating frequencies of the first and second ring oscillators FEOL_RO and BEOL_RO included in the semiconductor devices may have a certain relationship with minimum operating voltages of the semiconductor devices. To model the relationship, in the method of FIG. 5, minimum operating voltages of the plurality of semiconductor devices of the same kind and operating frequencies of the first and second ring oscillators FEOL_RO and BEOL_RO included in the semiconductor devices are measured, and the measured data are set as population data for modeling.

In some embodiments, the minimum operating voltages of the semiconductor devices may be measured for various operating frequencies. That is, a semiconductor device may operate at a first operating frequency and a second operating frequency which are different from each other. A first minimum operating voltage required for the semiconductor device to operate normally at the first operating frequency and a second minimum operating voltage required for the semiconductor device to operate normally at the second operating frequency may be measured and may be different from each other. The first minimum operating voltage for normal operation at the first operating frequency and the second minimum operating voltage for normal operation at the second operating frequency may be stored in a DVFS table. In an embodiment in which a semiconductor device to be tested has a varying operating frequency, a minimum operating voltage required for each operating frequency may be measured.

When the semiconductor device 100 to be measured is an AP, the semiconductor device 100 may operate at an operating frequency of, for example, 0.5 to 2 GHz. A minimum operating voltage required for the semiconductor device 100 to operate normally within this operating frequency range may vary according to the operating frequency. The measurement equipment 200 may measure a minimum operating voltage required by the semiconductor device 100 for each of a plurality of operating frequencies and store the measurement results for modeling.

The measurement equipment 200 may measure minimum operating voltages of a plurality of semiconductor devices 100 formed on one wafer W and operating frequencies of first and second ring oscillators FEOL_RO and BEOL_RO included in the plurality of the semiconductor devices 100 on the wafer W. In some embodiments, a plurality of semiconductor devices 100 to be measured may be formed on one wafer W; however, the semiconductor devices 100 may also include a plurality of semiconductor devices formed on a plurality of wafers W. For the accuracy of a model generated, measurements for as many semiconductor devices 100 as possible may be performed. That is, the more semiconductor devices from which measurements are taken the mores accurate the model will be.

Further, in some embodiments, the operating frequencies of a plurality of the first ring oscillators FEOL_RO and the operating frequencies of a plurality of the second ring oscillators BEOL_RO may be measured in different temperature environments. That is, the operating frequencies of the first ring oscillators FEOL_RO may be measured in a first temperature condition, and the operating frequencies of the second ring oscillators BEOL_RO may be measured in a second temperature condition different from the first temperature condition, for example, higher than the first temperature condition. In some embodiments, the first temperature condition may be a room temperature, and the second temperature may be a high temperature which is higher than the room temperature, for example, 80° C.

As described above, each of the second ring oscillators BEOL_RO includes the resistors 224 connected between adjacent NOT gates 223 of the plurality of NOT gates 223 and between the final NOT gate 223 of the plurality of NOT gates 223 and the AND gate 221. When the temperature condition rises during the operation of the second ring oscillators BEOL_RO, a resistance value of the resistor 224 may increase, thereby affecting the operating frequency of each of the second ring oscillators BEOL_RO.

Therefore, the operating frequencies of the second ring oscillators BEOL_RO may be measured in the second temperature condition higher than the first temperature condition, so that the second ring oscillators BEOL_RO may best reflect the thermal characteristics of the semiconductor devices 100, that is, the operating speed characteristics of the semiconductor devices 100 in a high temperature environment.

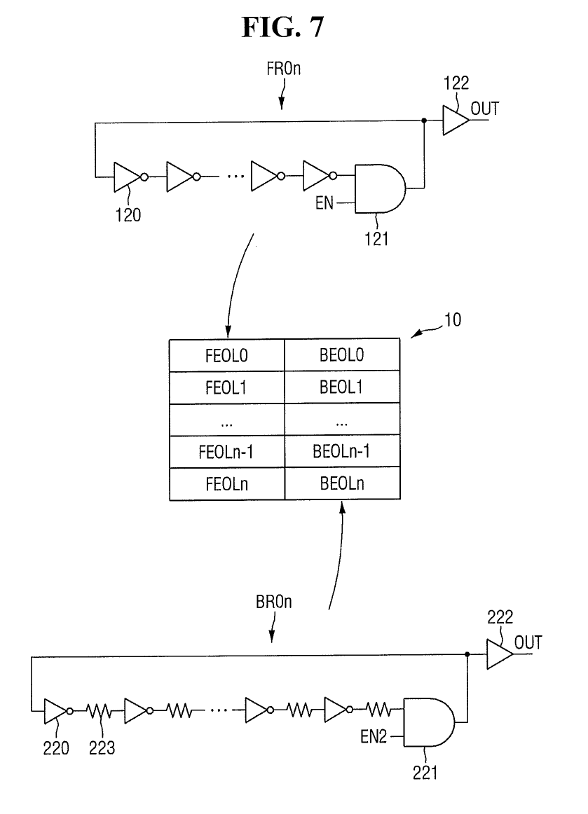

FIG. 7 is a schematic diagram illustrating a table 10 obtained by performing the method of testing a semiconductor device according to the embodiment of FIG. 5.

Referring to FIG. 7, respective measured operating frequencies of a plurality of the first ring oscillators FEOL_RO and a plurality of the second ring oscillators BEOL_RO are stored in the form of the table 10.

Specifically, respective operating frequencies FEOL0 through FEOLn of the plurality of the first ring oscillators FEOL_RO may be stored in the form of the table 10. The respective operating frequencies FEOL0 through FEOLn of the plurality of the first ring oscillators FEOL_RO may be different because each of the first ring oscillators FEOL_RO may be composed of various types of transistors. For example, some of the first ring oscillators FEOL_RO may be composed of transistors RVT having a regular voltage threshold described above and illustrated in FIG. 4A, and some of the first ring oscillators FEOL_RO may be composed of transistors SLVT having a super low threshold voltage described above and illustrated in FIG. 4B. The operating frequencies FEOL0 through FEOLn of the first ring oscillators FEOL_RO may be related to speed characteristics of transistors constituting the first ring oscillators FEOL_RO and may be related to speed characteristics of transistors in a block to which the first ring oscillators FEOL_RO belong.

Likewise, a plurality of second ring oscillators BEOL_RO may have operating frequencies BEOL0 through BEOLn, respectively. The operating frequencies BEOL0 through BEOLn of the plurality of the second ring oscillators BEOL_RO may be stored in the form of the table 10. The operating frequencies BEOL0 through BEOLn of the second ring oscillators BEOL_RO may be related to speed characteristics of transistors constituting the second ring oscillators BEOL_RO and may be related to speed characteristics of transistors in a block to which the second ring oscillators BEOL_RO belong.

Returning to FIG. 5, a model between the measured minimum operating voltages of the semiconductor devices 100 and the operating frequencies of the plurality of ring oscillators included in the semiconductor devices 100 is generated (operation S110).

In some embodiments, the model may include a first model between the minimum operating voltages of the semiconductor devices 100 and the operating frequencies of the first ring oscillators FEOL_RO and a second model between the minimum operating voltages of the semiconductor devices 100 and the operating frequencies of the second ring oscillators BEOL_RO.

In some embodiments, the model between the minimum operating voltages of the semiconductor devices 100 and the operating frequencies of the first and second ring oscillators FEOL_RO and BEOL_RO included in the semiconductor devices 100 may include a regression model.

That is, the first model may include a regression model which sets the measured minimum operating voltages of the semiconductor devices 100 as a dependent variable and in which the operating frequencies of the first ring oscillators FEOL_RO serve as an independent variable and, respectively, are given weights having a correlation with the minimum operating voltages.

In addition, the second model may include a regression model which sets the measured minimum operating voltages of the semiconductor devices 100 as a dependent variable and in which the operating frequencies of the second ring oscillators BEOL_RO serve as an independent variable and, respectively, are given weights having a correlation with the minimum operating voltages.

The first model generated according to a method of testing a semiconductor device according to some embodiments may be expressed by Equation (1):

LVCC=a₁×FRO1+a₂×FRO2+ . . . +aₙ₋₁×FROn-1+aₙ×FROn+C₁, (1)

where LVCC is a minimum operating voltage of a semiconductor device, FRO1, FRO2 . . . FROn-1 and FROn respectively indicate operating frequencies of a plurality of the first ring oscillators included in the semiconductor device 100, a₁ through aₙ are weights having a correlation with the minimum operating voltages, and C₁ is a constant.

The second model generated according to the method of testing a semiconductor device according to the embodiments may be expressed by Equation (2):

LVCC=b₁×BRO1+b₂×BRO2+ . . . +bₙ₋₁×BROn-1+bₙ×BROn+C₂, (2)

where BRO1, BRO2 . . . BROn-1 and BROn respectively indicate operating frequencies of a plurality of the second ring oscillators included in the semiconductor device 100, b₁ through bₙ are weights having a correlation with the minimum operating voltages, and C₂ is a constant.

In some embodiments, the above regression models may be expressed by Equation (3):

LVCC=a₁×FRO1+a₂×FRO2+ . . . +aₙ₋₁×FROn-1+aₙ×FROn+a_{f}×freq+C₃

LVCC=b₁×BRO1+b₂×BRO2+ . . . +bₙ₋₁×BROn-1+bₙ×BROn+b_{f}×freq+C₄ (3).

Here, freq is an operating frequency of a semiconductor device, a_{f} and b_{f} are weights, and C₃ and C₄ are constants. That is, the relationship (represented by Equation (3)) between a minimum operating voltage of a semiconductor device and operating frequencies of first ring oscillators FEOL_RO or second ring oscillators BEOL_RO included in the semiconductor device may also be generated in view of an operating frequency of the semiconductor device.

When modeling is performed through regression analysis, a method of least squares or a maximum likelihood method may be used; however, the present inventive concepts are not limited to these methods.

Referring again to FIG. 5, the operating frequencies of the plurality of the first ring oscillators FEOL_RO and the plurality of the second ring oscillators BEOL_RO in a target semiconductor device, or chip, are measured (S120).

The target semiconductor device may be of the same type as the semiconductor devices whose minimum operating voltages and operating frequencies were measured to generate the above-described model. Therefore, the operating voltage of the target semiconductor device may be predicted using the model.

The operating frequencies of the plurality of the first ring oscillators FEOL_RO and the plurality of the second ring oscillators BEOL_RO included in the target semiconductor device may be measured using the measuring equipment 200 of FIG. 4. Therefore, the measurement equipment 200 may input test signals to terminals connected to the exposed first and second ring oscillators FEOL_RO and BEOL_RO and receive test response signals before the manufactured target semiconductor device is sawed and packaged.

In the process of generating a model using a plurality of semiconductor devices 100, a minimum operating voltage of a first functional block 110 included in each of the semiconductor devices 100 and operating frequencies of ring oscillators included in the first function block 110 were used. Therefore, the operating frequencies of the plurality of the first ring oscillators FEOL_RO and the plurality of the second ring oscillators BEOL_RO included in the first functional block 110 of the target semiconductor device may also be measured.

As described above, the measured operating frequencies of the first ring oscillators FEOL_RO of the target semiconductor device may indicate response speed characteristics of the target semiconductor device, and the measured operating frequencies of the second ring oscillators BEOL_RO of the target semiconductor device may indicate thermal characteristics of the target semiconductor device.

As in the process of generating the first and second models of the operating frequencies of the plurality of the first ring oscillators FEOL_RO and the plurality of the second oscillators BEOL_RO, the operating frequencies of the plurality of the first ring oscillators FEOL_RO of the target semiconductor device may be measured in a first temperature condition, and the operating frequencies of the plurality of the second ring oscillators BEOL_RO of the second ring oscillators BEOL_RO of the target semiconductor device may be measured in a second temperature condition different than the first temperature condition, for example, higher than the first temperature condition.

Next, the first measurement value FEOL_RO TOTAL VALUE is calculated using the operating frequencies of the plurality of the first ring oscillators FEOL_RO of the target semiconductor device and the first model, and a second measurement value BEOL_RO TOTAL VALUE is calculated using the operating frequencies of the plurality of the second ring oscillators BEOL_RO of the target semiconductor device and the second model (S130).

The first measurement value FEOL_RO TOTAL VALUE may be calculated by substituting the measured operating frequencies of the plurality of the first ring oscillators FEOL_RO of the target semiconductor device into the first model. The second measurement value BEOL_RO TOTAL VALUE may be calculated by substituting the measured operating frequencies of the second ring oscillators BEOL_RO of the target semiconductor device into the second model.

Next, a high temperature compensation voltage of the target semiconductor device may be determined based on the first measurement value FEOL_RO TOTAL VALUE and the second measurement value BEOL_RO TOTAL VALUE (S140).

In some embodiments, the high temperature compensation voltage of the target semiconductor device may be determined by subtracting the second measurement value BEOL_RO TOTAL VALUE obtained from the operating frequencies of the plurality of the second ring oscillators BEOL_RO and the second model from the first measurement value FEOL_RO TOTAL VALUE obtained from the operating frequencies of the plurality of the first ring oscillator FEOL_RO and the first model.

As described above, the operating frequencies of the second ring oscillators BEOL_RO including resistance components may indicate the thermal characteristics of the circuit of a semiconductor device 100. The high temperature compensation voltage of the target semiconductor device may be predicted using the first and second models obtained from the plurality of semiconductor devices and the operating frequencies of the first and second ring oscillators FEOL_RO and BEOL_RO of the target semiconductor device.

That is, as the target semiconductor device operates, the temperature of the target semiconductor device may rise, thereby deteriorating the response characteristics of the circuit of the target semiconductor device. Therefore, at a set operating frequency, the target semiconductor device may operate normally at a normal temperature, but may not operate normally in a high temperature environment. To solve this problem, a power supply voltage of the target semiconductor device may be increased, so that the target semiconductor device may operate at a set operating frequency in the high temperature environment. However, it is not easy to obtain the high temperature compensation voltage because the high temperature compensation voltage may be obtained only in a trial and error manner in a real high temperature environment.

However, in the method of the present inventive concepts, the high temperature compensation voltage may be statistically calculated using operating frequencies of the plurality of the first ring oscillators FEOL_RO and the plurality of the second ring oscillators BEOL_RO and minimum operating voltages of the semiconductor devices. That is, a regression model representing thermal characteristics of circuits of semiconductor devices 100 is generated using the first model generated between minimum operating voltages of the semiconductor devices 100 and the operating frequencies of the plurality of the first ring oscillators FEOL_RO and the second model generated between the minimum operating voltages of the semiconductor devices 100 and the operating frequencies of the plurality of the second ring oscillators BEOL_RO. Then, operating frequencies of the plurality of the first ring oscillators FEOL_RO and the plurality of the second ring oscillators BEOL_RO of the target semiconductor device are measured and substituted into the first and second models to predict a high temperature compensation voltage.

Next, a DVFS table is modified based on the high temperature compensation voltage (S150). Each of the first through third functional blocks 110 through 130 included in a semiconductor device 100 stores a DVFS table in which the relationship between each operating frequency and a minimum operating voltage is set. By modifying the DVFS table, the operating condition of the semiconductor device 100 may be changed.

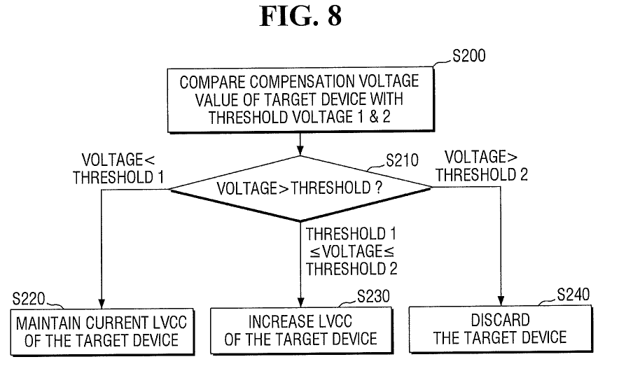

Modifying the DVFS table using the high temperature compensation voltage will be described in more detail with reference to FIG. 8.

FIG. 8 is a flowchart illustrating a method of testing a semiconductor device according to some embodiments of the present inventive concepts.

Referring to FIG. 8, the method of FIG. 8 may include comparing a high temperature compensation voltage of a target semiconductor device or chip with a predetermined first threshold voltage and a predetermined second threshold voltage (S200). The method may further include maintaining a current minimum operating voltage (LVCC) of the target semiconductor device (S220), increasing the minimum operating voltage of the target semiconductor device (S230), or discarding the target semiconductor device (S240) based on a result of comparing the high temperature compensation voltage of the target semiconductor device with the predetermined first threshold voltage and the predetermined second threshold voltage.

Specifically, when the calculated high temperature compensation voltage of the target semiconductor device is lower than the predetermined first threshold voltage, the current minimum operating voltage of the target semiconductor device may be maintained, and no high temperature compensation voltage may be set. In such an embodiment, a DVFS table included in the target semiconductor device may not be modified, and values stored in the DVFS table may be maintained.

When the calculated high temperature compensation voltage of the target semiconductor device is between the predetermined first threshold voltage and the predetermined second threshold voltage, that is, greater than or equal to the predetermined first threshold voltage and less than or equal to the predetermined second threshold voltage, the minimum operating voltage of the target semiconductor device may be increased so that the target semiconductor device may operate at a set operating frequency in a high temperature environment. The DVFS table included in the target semiconductor device may be modified, and values stored in the DVFS table may be changed.

By modifying the contents of the DVFS table stored in the target semiconductor device, the minimum operating voltage of the target semiconductor device may be increased.

When the calculated high temperature compensation voltage of the target semiconductor device is greater than the predetermined second threshold voltage, the target semiconductor device may be discarded. In such an embodiment, the high temperature compensation voltage of the target semiconductor device determined by the above-described process may not be applied due to the operating characteristics of the target semiconductor device and the power source environment of an electronic device in which the target semiconductor device is employed, and, as a result, the target semiconductor device is discarded.

In conclusion, the method of testing a semiconductor device according to the embodiments of the present inventive concepts may ensure normal operation of a target semiconductor device in a high temperature environment by setting a high temperature compensation voltage of the target semiconductor device.

In some other embodiments, the high temperature compensation voltage may also be compared with a predetermined third threshold voltage. That is, when the high temperature compensation voltage is greater than the predetermined second threshold voltage, the high temperature compensation voltage may be compared with the predetermined third threshold voltage greater than the second threshold voltage. When the high temperature compensation voltage of the target semiconductor device is between the predetermined second threshold voltage and the predetermined third threshold voltage, that is, greater than or equal to the predetermined second threshold voltage and less than or equal to the predetermined third threshold voltage, the DVFS table may be modified to increase the minimum operating voltage of the target semiconductor device. When the high temperature compensation voltage is greater than the predetermined third threshold voltage, the target semiconductor device may be discarded.

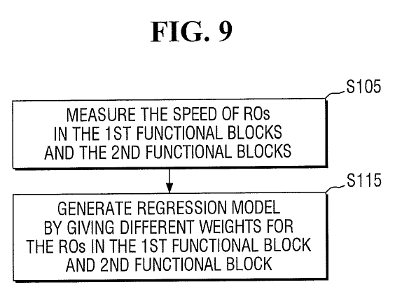

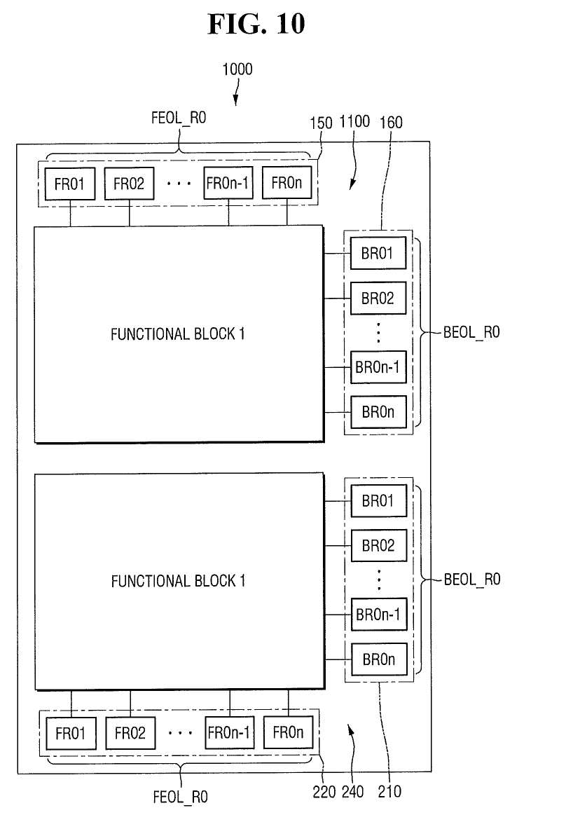

FIG. 9 is a flowchart illustrating a method of testing a semiconductor device according to some embodiments of the present inventive concepts. FIG. 10 is a block diagram of a semiconductor device 1000 to which the method of testing a semiconductor device according to the embodiment of FIG. 9 may be applied.

Referring to FIG. 9, the method of testing a semiconductor device may include some different processes from the method of testing a semiconductor device according to the above-described embodiment of FIG. 5. That is, a model between a minimum operating voltage of a semiconductor device and operating frequencies of ring oscillators included in the semiconductor device may be generated using operating frequencies of ring oscillators included in both first and second functional blocks 110 and 120 that are different from each other. However, the inventive concepts are not limited thereto, and ring oscillators included in all functional blocks of the semiconductor device as well as the ring oscillators included in the first and second functional blocks 110 and 120 may be used. That is, a model between a minimum operating voltage of a semiconductor device and operating frequencies of ring oscillators included in multiple functional blocks of a plurality of functional blocks of a semiconductor device that are different from each other may be used.

Referring to FIG. 10, the semiconductor device 1000 includes a first group 150 including first ring oscillators FEOL_RO in a first functional block 1100 and a second group 160 including second ring oscillators BEOL_RO in the first functional block 1100, a third group 250 including the first ring oscillators FEOL_RO in a second functional block 240 and a fourth group 260 including the second ring oscillators BEOL_RO in the second functional block 240. The first ring oscillators FEOL_RO and the second ring oscillators BEOL_RO are similar to those described in connection with FIG. 2.

In the method of testing a semiconductor device according to the embodiment of FIG. 9 and FIG. 10, a minimum operating voltage of the first functional block 1100 of the semiconductor device 1000 and operating frequencies of the first group 150 including the first ring oscillators FEOL_RO and the second group 160 including the second ring oscillators BEOL_RO included in the first functional block 1100 are measured. Then, a minimum operating voltage of the second functional block 240 of the semiconductor device 1000 and operating frequencies of the third group 250 including the first ring oscillators FEOL_RO and the fourth group 260 including the second ring oscillators BEOL_RO included in the second functional block 240 are measured. The minimum operating voltage of the first functional block 1100 and the minimum operating voltage of the second functional block 240 may be measured, for example, simultaneously by measurement equipment 200. Similarly, the operating frequencies of the first through fourth groups 150, 160, 250 and 260, respectively, may also be measured simultaneously.

Using the measured minimum operating voltages of the first and second functional blocks 1100 and 240 and the measured operating frequencies of the ring oscillators in the first through fourth groups 150, 160, 250 and 260, a model representing the correlation between the minimum operating voltages and the operating frequencies is generated.

The model may be generated as follows. First, a first model representing the correlation between the minimum operating voltage of the first functional block 1100 and the operating frequencies of the first ring oscillators FEOL_RO in the first group 150 of the first functional block 1100 and the first ring oscillators FEOL_RO in the third group 250 of the second function block 240 is generated. The first model may include a first sub-model representing the correlation between the minimum operating voltage of the first functional block 1100 and the operating frequencies of the first ring oscillators FEOL_RO in the first group 150 and the third group 250 and a second sub-model representing the correlation between the minimum operating voltage of the second functional block 240 and the operating frequencies of the first ring oscillators FEOL_RO in the first group 150 and the third group 250.

That is, while the operating frequencies of the first ring oscillators FEOL_RO included in the first functional block 110 are used to generate a model of the minimum operating voltage of the first functional block 110 in the previous embodiment, the operating frequencies of the first ring oscillators FEOL_RO included in both the first functional block 1100 and the second functional block 240 are used to generate the first model in the test method according to the embodiment of FIG. 9.

In some embodiments, the first sub-model related to the minimum operating voltage of the first functional block 1100 may be generated by giving different weights to the operating frequencies of the first ring oscillators FEOL_RO included in the first group 150 and the operating frequencies of the first ring oscillators FEOL_RO included in the third group 250.

The first functional block 1100 and the second functional block 240 in the semiconductor device 1000 perform different functions and are separated from each other.

However, the two functional blocks 1100 and 240 may be connected by, for example, an interface circuit. Also, circuit effects of circuit components included in the first functional block 1100 may affect the circuit operation of the second functional block 240. Conversely, circuit effects of circuit components included in the second functional block 240 may affect the circuit operation of the first functional block 1100.

In the method of testing a semiconductor device according to the embodiment of FIG. 9, the first sub-model representing a correlation between the minimum operating voltage of the first functional block 1100 and the operating frequencies of the first ring oscillators FEOL_RO is generated by giving different weights to the operation frequencies of the first ring oscillators FEOL_RO included in the first group 150 and the operating frequencies of the first ring oscillators FEOL_RO included in the third group 250. In some embodiments, the weight given to the operating frequencies of the first ring oscillators FEOL_RO included in the first group 150 may be greater than the weight given to the operating frequencies of the first ring oscillators FEOL_RO included in the third group 250.

As a result, the first sub-model is generated such that the operating frequencies of the first ring oscillators FEOL_RO included in the first group 150 have a greater influence on the minimum operating voltage of the first functional block 1100 than the first ring oscillators FEOL_RO included in the third group 250 of the second functional block 240.

Like the first sub-model, the second sub-model representing the correlation between the minimum operating voltage of the second functional block 240 and the operating frequencies of the first ring oscillators FEOL_RO included in the first group 150 and the third group 250 may be generated by giving different weights to the operating frequencies of the first ring oscillators FEOL_RO included in the first group 150 and the third group 250. In some embodiments, the weight given to the operating frequencies of the first ring oscillators FEOL_RO included in the third group 250 may be greater than the weight given to the operating frequencies of the first ring oscillators FEOL_RO included in the first group 150.

As a result, the second sub-model is generated such that the operating frequencies of the first ring oscillators FEOL_RO included in the third group 250 have a greater influence on the minimum operating voltage of the second functional block 240 than the first ring oscillators FEOL_RO included in the first group 150 of the first functional block 1100.

In the method of testing a semiconductor device according to the embodiment of FIG. 9, the second model representing the correlation between the minimum operating voltage of the first functional block 1100 and the operating frequencies of the second ring oscillators BEOL_RO included in the second group 160 of the first functional block 1100 and the fourth group 260 of the second functional block 240 is generated. The second model may include a third sub-model representing the correlation between the minimum operating voltage of the first functional block 1100 and the operating frequencies of the second ring oscillators BEOL_RO included in the second group 160 and the fourth group 260 and a fourth sub-model representing the correlation between the minimum operating voltage of the second functional block 240 and the operating frequencies of the second ring oscillators BEOL_RO included in the second group 160 and the fourth group 260.

Like the first sub-model and the second sub-model, the third sub-model and the fourth sub-model may be generated by giving a different weight to each group. In some embodiments, in the third sub-model, the weight given to the operating frequencies of the second ring oscillators BEOL_RO included in the second group 160 may be greater than the weight given to the operating frequencies of the second ring oscillators BEOL_RO included in the fourth group 260. In some embodiments, in the fourth sub-model, the weight given to the operating frequencies of the second ring oscillators BEOL_RO included in the fourth group 260 may be greater than the weight given to the operating frequencies of the second ring oscillators BEOL_RO included in the second group 160.

As a result, the third sub-model is generated such that the operating frequencies of the second ring oscillators BEOL_RO included in the second group 160 have a greater influence on the minimum operating voltage of the first functional block 1100 than the second ring oscillators BEOL_RO included in the fourth group 260 of the second functional block 240. In addition, the fourth sub-model is generated such that the operating frequencies of the second ring oscillators BEOL_RO included in the fourth group 260 have a greater influence on the minimum operating voltage of the second functional block 240 than the second ring oscillators BEOL_RO included in the second group 160 of the first functional block 1100

Through the above process, the first model between the minimum operating voltage of the first functional block 1100 and the operating frequencies of the first and second ring oscillators FEOL_RO and BEOL_RO, respectively, and the second model between the minimum operating voltage of the second functional block 120 and the operating frequencies of the first and second ring oscillators FEOL_RO and BEOL_RO, respectively, are generated.

A high temperature compensation voltage of a target semiconductor device may be determined using the first model and the second model. That is, the operating frequencies of the first and second ring oscillators FEOL_RO and BEOL_RO, respectively, included in the first through fourth groups 150, 160, 250 and 260 in the first functional block 1100 and the second functional block 240, respectively, of the target semiconductor device are measured.

The measured operating frequencies of the first ring oscillators FEOL_RO in the first group 150 and the third group 250 and the measured operating frequencies of the second ring oscillators BEOL_RO in the second group 160 and the fourth group 260 are provided to the first model and the second model. Then, high temperature compensation voltages of the first functional block 1100 and the second functional block 240 may be determined.

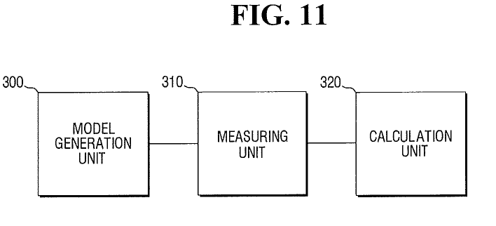

FIG. 11 is a block diagram of a system for testing a semiconductor device according to some embodiments of the present inventive concepts.

Referring to FIG. 11, the system may include a model generation unit 300, a measuring unit 310, and a calculation unit 320.

The measuring unit 310 may measure minimum operating voltages of a plurality of semiconductor devices and operating frequencies of first and second ring oscillators included in the semiconductor devices. The measuring unit 310 may include, for example, the measurement equipment 200 of FIG. 4 to measure a plurality of semiconductor devices; however, the present inventive concepts are not limited thereto.

The model generation unit 300 receives the results of measuring the semiconductor devices from the measuring unit 310 and generates a model between the minimum operating voltages of the semiconductor devices and the operating frequencies of the first and second ring oscillators included in the semiconductor devices using the measurement results, as described above. The model generation unit 300 may store the generated model in, for example, a memory.

Then, the measuring unit 310 receives a target semiconductor device and the measuring unit 310 measures the operating frequencies of the first and second ring oscillators included in the target semiconductor device. In some embodiments, the measuring unit 310 may simultaneously measure the operating frequencies of the first and second ring oscillators of a plurality of target semiconductors included in one wafer W.

The calculation unit 320 may determine a high temperature compensation voltage of the target semiconductor device by using the measured operating frequencies of the first and second ring oscillators included in the target semiconductor device and the model generated by the model generation unit 300, as described above.

Although a few embodiments of the present general inventive concepts have been shown and described, it will be appreciated by those skilled in the art that changes may be made in these embodiments without departing from the principles and spirit of the general inventive concepts, the scope of which is defined in the appended claims and their equivalents.

What is claimed is:

1. A method of testing a semiconductor device, the method comprising:
measuring minimum operating voltages of a plurality of semiconductor devices and operating frequencies of first and second ring oscillators included in the semiconductor devices, wherein the first ring oscillators comprise a first circuit configuration and the second ring oscillators comprise a second circuit configuration different from the first circuit configuration;
generating a first model representing a correlation between the operating frequencies of the first ring oscillators in the semiconductor devices and the minimum operating voltages of the semiconductor devices;
generating a second model representing a correlation between the operating frequencies of the second ring oscillators in the semiconductor devices and the minimum operating voltages of the semiconductor devices;
measuring operating frequencies of first ring oscillators and second ring oscillators included in a target semiconductor device;
calculating a first measurement value using the operating frequencies of the first ring oscillators in the target semiconductor device and the first model;
calculating a second measurement value using the operating frequencies of the second ring oscillators in the target semiconductor device and the second model;
determining a high temperature compensation voltage of the target semiconductor device based on the first measurement value and the second measurement value; and
modifying a dynamic voltage and frequency scaling (DVFS) table of the target semiconductor device according to the high temperature compensation voltage.

2. The method of claim 1, wherein the determining of the high temperature compensation voltage of the target semiconductor device comprises calculating a difference between the first measurement value and the second measurement value of the target semiconductor device.

3. The method of claim 1, wherein the operating frequencies of the first ring oscillators of the target semiconductor device are measured in a first temperature condition, and the operating frequencies of the second ring oscillators of the target semiconductor device are measured in a second temperature condition higher than the first temperature condition.

4. The method of claim 1, wherein the generating of the first model comprises generating a regression model between the operating frequencies of the first ring oscillators and the minimum operating voltages of the semiconductor devices.

5. The method of claim 1, wherein the generating of the second model comprises generating a regression model between the operating frequencies of the second ring oscillators and the minimum operating voltages of the semiconductor devices.

6. The method of claim 1, wherein the operating frequencies of the first ring oscillators are different from the operating frequencies of the second ring oscillators.

7. The method of claim 6, wherein the operating frequencies of the first ring oscillators are greater than the operating frequencies of the second ring oscillators.

8. The method of claim 1, wherein each of the second ring oscillators comprises a plurality of inverters connected in series and a plurality of resistors connected between the inverters.

9. The method of claim 1, wherein each of the semiconductor devices comprises a first functional block and a second functional block different from each other, the generating of the first model comprises generating a first sub-model representing a correlation between operating frequencies of first ring oscillators in the first and second functional blocks and a minimum operating voltage of the first functional block and a second sub-model representing a correlation between operating frequencies of second ring oscillators in the first and second functional blocks and the minimum operating voltage of the first functional block and generating of the second model comprises generating a third sub-model representing a correlation between operating frequencies of first ring oscillators in the first and second functional blocks and a minimum operating voltage of the second functional block and a fourth sub-model representing a correlation between operating frequencies of second ring oscillators in the first and second functional blocks and the minimum operating voltage of the second functional block.

10. The method of claim 9, wherein the first ring oscillators in the first and second functional blocks comprise a first group in the first functional block and a second group in the second functional block, and the generating of the first sub-model and the second sub-model comprises generating a regression model by giving different weights to the first group and the second group.

11. The method of claim 1, further comprising comparing the high temperature voltage of the target semiconductor device with predetermined threshold voltages.

12. The method of claim 11, wherein the predetermined threshold voltages comprise a first threshold voltage and a second threshold voltage greater than the first threshold voltage, and the comparing of the high temperature compensation voltage of the target semiconductor device with the predetermined threshold voltages comprises maintaining a minimum operating voltage of the target semiconductor device when the high temperature compensation voltage is smaller than the first threshold voltage, increasing the minimum operating voltage of the target semiconductor device when the high temperature compensation voltage is between the first threshold voltage and the second threshold voltage, and discarding the target semiconductor device when the high temperature compensation voltage is greater than the second threshold voltage.

13. A system for testing a semiconductor device, the system comprising:
a measuring unit measuring minimum operating voltages of a plurality of semiconductor devices and operating frequencies of first and second ring oscillators included in the semiconductor devices, wherein the first ring oscillators comprise a first circuit configuration and the second ring oscillators comprise a second circuit configuration different from the first circuit configuration;
a model generation unit generating a first model representing a correlation between the operating frequencies of the first ring oscillators in the semiconductor devices and the minimum operating voltages of the semiconductor devices and generating a second model representing a correlation between the operating frequencies of the second ring oscillators in the semiconductor devices and the minimum operating voltages of the semiconductor devices; and
a calculation unit receiving operating frequencies of first ring oscillators and second ring oscillators included in a target semiconductor device from the measuring unit, calculating a first measurement value using the operating frequencies of the first ring oscillators in the target semiconductor device and the first model, calculating a second measurement value using the operating frequencies of the second ring oscillators in the target semiconductor device and the second model, and determining a high temperature compensation voltage of the target semiconductor device based on the first measurement value and the second measurement value.

14. The system of claim 13, wherein the first model comprises a regression model representing a correlation between the operating frequencies of the first ring oscillators and the minimum operating voltages of the semiconductor devices, and the second model comprises a regression model representing a correlation between the operating frequencies of the second ring oscillators and the minimum operating voltages of the semiconductor devices.

15. The system of claim 13, wherein each of the second ring oscillators comprises a plurality of inverters connected in series and a plurality of resistors connected between the inverters.

16. A method of testing a semiconductor device, the method comprising:
measuring a minimum operating voltage of at least one functional block included in each of a plurality of semiconductor devices and operating frequencies of first and second ring oscillators included in the at least one functional block, wherein the first ring oscillators comprise a first circuit configuration and the second ring oscillators comprise a second circuit configuration different from the first circuit configuration;
generating a first model representing a correlation between the operating frequencies of the first ring oscillators in the at least one functional block and the minimum operating voltage of the at least one functional block;
generating a second model representing a correlation between the operating frequencies of the second ring oscillators in the at least one functional block and the minimum operating voltage of the at least one functional block;
measuring operating frequencies of first ring oscillators and second ring oscillators included in a target semiconductor device;
calculating a first measurement value using the operating frequencies of the first ring oscillators in the target semiconductor device and the first model;
calculating a second measurement value using the operating frequencies of the second ring oscillators in the target semiconductor device and the second model; and
determining a high temperature compensation voltage of the target semiconductor device based on the first measurement value and the second measurement value.

17. The method of claim 16, wherein the at least one functional block comprise a first functional block and a second functional block different from each other, the generating of the first model comprises generating a first sub-model representing a correlation between the operating frequencies of first ring oscillators in the first and second functional blocks and a minimum operating voltage of the first functional block and a second sub-model representing a correlation between operating frequencies of second ring oscillators in the first and second functional blocks and the minimum operating voltage of the first functional block and generating of the second model comprises generating a third sub-model representing a correlation between the operating frequencies of the first ring oscillators in the first and second functional blocks and a minimum operating voltage of the second functional block and a fourth sub-model representing a correlation between the operating frequencies of the second ring oscillators in the first and second functional blocks and the minimum operating voltage of the second functional block.

18. The method of claim 16, wherein each of the second ring oscillators comprises a plurality of inverters connected in series and a plurality of resistors connected between the inverters.

19. The method of claim 16, wherein the determining of the high temperature compensation voltage of the target semiconductor device comprises calculating a difference between the first measurement value and the second measurement value of the target semiconductor device.

20. The method of claim 16, wherein the operating frequencies of the first ring oscillators of the target semiconductor device are measured in a first temperature condition, and the operating frequencies of the second ring oscillators of the target semiconductor device are measured in a second temperature condition higher than the first temperature condition.
